(19) United States
(12) Patent Application Publication
(10) Pub. No.: US 2017/0256470 A1
(43) Pub. Date: Sep. 7, 2017

(54) WIRING SUBSTRATE AND METHOD FOR MANUFACTURING THE SAME

(71) Applicant: IBIDEN CO., LTD., Ogaki (JP)

(72) Inventors: Hajime SAKAMOTO, Ogaki (JP); Keisuke SHIMIZU, Ogaki (JP)

(73) Assignee: IBIDEN CO., LTD., Ogaki (JP)

(21) Appl. No.: 15/451,473

(22) Filed: Mar. 7, 2017

(30) Foreign Application Priority Data
Mar. 7, 2016 (JP) 2016-043014

(51) Int. Cl. H01L 23/16; H01L 21/54; H01L 21/48; H01L 21/56; H01L 23/538; H01L 23/31

(52) U.S. Cl. CPC H01L 23/16; H01L 23/5389; H01L 23/5383; H01L 23/5386; H01L 23/3114; H01L 21/4853; H01L 21/4857; H01L 21/565; H01L 21/54

(57) ABSTRACT

A wiring substrate includes insulating layers including a first insulating layer such that the first insulating layer is positioned at one end of the insulating layers in lamination direction and has an accommodating portion through the first insulating layer, conductive layers laminated on the insulating layers and including a first conductive layer formed on one end side of the first insulating layer in the lamination direction and a second conductive layer formed on the opposite side, and a semiconductor element accommodated in the accommodating portion of the first insulating layer. The insulating layers include the first insulating layer including reinforcing material and a second insulating layer laminated on the first insulating layer such that the second insulating layer is covering the second conductive layer and the semiconductor element and filling gap formed between the first insulating layer and semiconductor element in the accommodating portion and does not contain reinforcing material.

### CROSS-REFERENCE TO RELATED APPLICATIONS

The present application is based upon and claims the benefit of priority to Japanese Patent Application No. 2016-043014, filed Mar. 7, 2016, the entire contents of which are incorporated herein by reference.

### BACKGROUND OF THE INVENTION

Field of the Invention

The present invention relates to a wiring substrate that is formed by laminating multiple conductive layers and multiple insulating layers, and relates to a method for manufacturing the wiring substrate.

Description of Background Art

Japanese Patent Laid-Open Publication No. 2006-059992 describes a wiring substrate in which a semiconductor element is embedded. The entire contents of this publication are incorporated herein by reference.

### SUMMARY OF THE INVENTION

According to one aspect of the present invention, a wiring substrate includes insulating layers including a first insulating layer such that the first insulating layer is positioned at one end of the insulating layers in a lamination direction and has an accommodating portion penetrating through the first insulating layer, conductive layers laminated on the insulating layers and including a first conductive layer formed on one end side of the first insulating layer in the lamination direction and a second conductive layer formed on the opposite side of the first insulating layer with respect to the one end side in the lamination direction, and a semiconductor element accommodated in the accommodating portion of the first insulating layer. The insulating layers include the first insulating layer including a reinforcing material and a second insulating layer laminated on the first insulating layer such that the second insulating layer is covering the second conductive layer and the semiconductor element and filling a gap formed between the first insulating layer and the semiconductor element in the accommodating portion and does not contain a reinforcing material.

According to another aspect of the present invention, a method for manufacturing a wiring substrate includes forming, on a support member, insulating layers including a first insulating layer such that the first insulating layer is positioned at one end of the insulating layers in a lamination direction and has an accommodating portion penetrating through the first insulating layer, and conductive layers laminated on the insulating layers and including a first conductive layer formed on one end side of the first insulating layer in the lamination direction and a second conductive layer formed on the opposite side of the first insulating layer with respect to the one end side in the lamination direction, and removing the support member from the insulating and conductive layers. The forming of the insulation and conductive layers includes forming the first conductive layer on the support member, forming the first insulating layer on the support member such that the first insulating layer covers the first conductive layer on the support member, forming the accommodating portion in the first insulating layer such that the accommodating portion penetrates through the first insulating layer, accommodating a semiconductor element in the accommodating portion of the first insulating layer such that the semiconductor element is positioned in the accommodating portion of the first insulating layer, forming the second conductive layer on the first insulating layer such that the second conductive layer is formed on the opposite side of the first insulating layer with respect to the first conductive layer, and forming the second insulation on the first insulating layer such that the second insulating layer covers the second conductive layer and the semiconductor element, fills a gap formed between the first insulating layer and the semiconductor element in the accommodating portion and does not contain a reinforcing material, the removing of the support member includes removing the support member from the first insulating layer such that the semiconductor element is accommodated in the accommodating portion of the first insulating layer before the support member is removed from the first insulating layer, and the insulating layers include the first insulating layer including a reinforcing material.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional side view of a wiring substrate according to a first embodiment of the present invention;

FIG. 2A-2C are cross-sectional side views illustrating manufacturing processes of the wiring substrate;

FIGS. 3A and 3B are cross-sectional side views illustrating manufacturing processes of the wiring substrate;

FIGS. 4A and 4B are cross-sectional side views illustrating manufacturing processes of the wiring substrate;

FIGS. 5A and 5B are cross-sectional side views illustrating manufacturing processes of the wiring substrate;

FIGS. 6A and 6B are cross-sectional side views illustrating manufacturing processes of the wiring substrate;

FIGS. 7A and 7B are cross-sectional side views illustrating manufacturing processes of the wiring substrate;

FIGS. 8A and 8B are cross-sectional side views illustrating manufacturing processes of the wiring substrate;

FIGS. 9A and 9B are cross-sectional side views illustrating manufacturing processes of the wiring substrate;

FIG. 10 is a cross-sectional side view illustrating a manufacturing process of the wiring substrate;

FIG. 11 is a cross-sectional side view illustrating a manufacturing process of the wiring substrate;

FIG. 12 is a cross-sectional side view illustrating a manufacturing process of the wiring substrate;

FIG. 13 is a cross-sectional side view illustrating a manufacturing process of the wiring substrate;

FIG. 14 is a cross-sectional side view illustrating a manufacturing process of the wiring substrate;

FIG. 15 is a cross-sectional side view illustrating a state in which the wiring substrate is used;

FIG. 16 is an enlarged cross-sectional side view of the wiring substrate;

FIG. 17 is a cross-sectional side view of a wiring substrate according to a second embodiment;

FIGS. 18A and 18B are cross-sectional side views illustrating manufacturing processes of the wiring substrate according to the second embodiment;

FIGS. 19A and 19B are cross-sectional side views illustrating manufacturing processes of the wiring substrate according to the second embodiment; and

FIG. 20 is a cross-sectional side view of a wiring substrate according to a modified embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

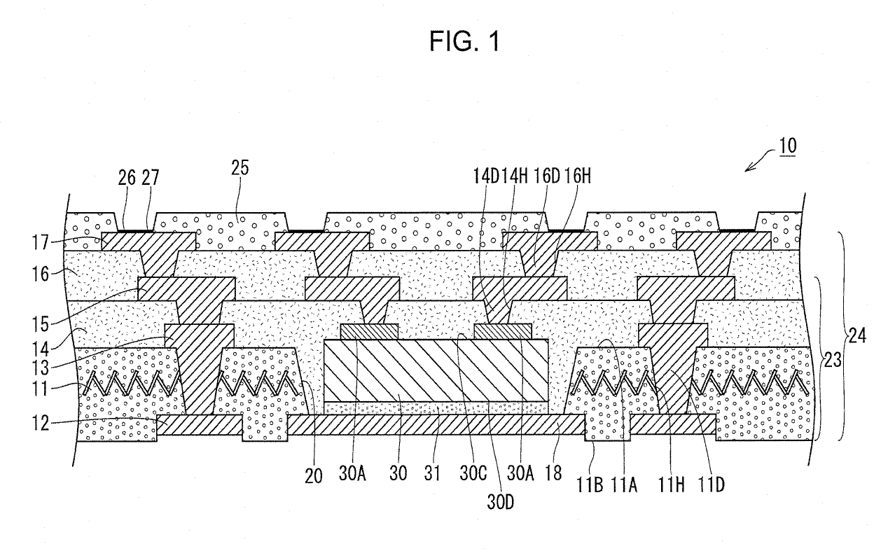

In the following, a first embodiment of the present invention is described with reference to FIG. 1-16. As illustrated in FIG. 1, a wiring substrate 10 of the present embodiment has a build-up layer 24 obtained by alternately laminating multiple insulating resin layers (11, 14, 16) (corresponding to “insulating layers” according to an embodiment of the present invention) and multiple conductive layers (12, 13, 15, 17) that each include conductive paths.

Among the multiple insulating resin layers (11, 14, 16) of the build-up layer 24, the first insulating resin layer 11 according to an embodiment of the present invention is formed at one end in a lamination direction. The second conductive layer 13 is laminated on a primary surface (11A) of the first insulating resin layer 11, the primary surface (11A) being a surface on an opposite side of the one end in the lamination direction. On the other hand, the first conductive layer 12 is formed on a secondary surface (11B) side of the first insulating resin layer 11, the secondary surface (11B) being on an opposite side of the primary surface (11A). The first conductive layer 12 is embedded on the secondary surface (11B) side of the first insulating resin layer 11 and is partially exposed on the secondary surface (11B). Further, a surface of the first conductive layer 12 on the secondary surface (11B) side of the first insulating resin layer 11 is positioned on an inner side of the secondary surface (11B) of the first insulating resin layer 11. In the present embodiment, a direction from the secondary surface (11B) toward the primary surface (11A) of the first insulating resin layer 11 is defined as “upward.”

Further, via holes (11H) and a cavity 20 (corresponding to an “accommodating part” according to an embodiment of the present invention) are formed in the first insulating resin layer 11. The via holes (11H) each have a tapered shape that is gradually reduced in diameter from the primary surface (11A) side toward the secondary surface (11B) side. The via holes (11H) are filled with plating and via conductors (11D) are formed. Then, due to the via conductors (11D) of the first insulating resin layer 11, the first conductive layer 12 and the second conductive layer 13 are connected to each other.

The cavity 20 has a truncated pyramid-shaped space that is gradually reduced in diameter from the primary surface (11A) side toward the secondary surface (11B), and penetrates the first insulating resin layer 11. Further, a portion of the first conductive layer 12 below the cavity 20 is a plane portion 18. An upper surface of the plane portion 18 is exposed as a bottom surface in the cavity 20.

A semiconductor element 30 is accommodated in the cavity 20. The semiconductor element 30 has an active surface (30C) on the primary surface (11A) side of the first insulating resin layer 11 and a non-active surface (30D) on the secondary surface (11B) side of the first insulating resin layer 11, terminals (30A, 30A) being provided on the active surface (30C) and no terminal being provided on the non-active surface (30D). The non-active surface (30D) is bonded to the plane portion 18 by an adhesive 31. Further, the semiconductor element 30 slightly protrudes from the cavity 20, and upper surfaces of the terminals (30A, 30A) are substantially flush with an upper surface of the second conductive layer 13.

The second insulating resin layer 14 covering the second conductive layer 13 is laminated on the primary surface (11A) of the first insulating resin layer 11. A portion of the second insulating resin layer 14 enters a gap between the semiconductor element 30 and an inner side surface of the cavity 20, and covers the semiconductor element 30. Further, the third conductive layer 15, the third insulating resin layer 16, and the fourth conductive layer 17 are formed in this order on an upper surface of the second insulating resin layer 14.

Multiple via holes (14H, 16H) are formed in the second and third insulating layers (14, 16). The via holes (14H, 16H) are filled with plating and multiple via conductors (14D, 16D) are formed. Then, due to the via conductors (14D) of the second insulating resin layer 14, the second conductive layer 13 and the third conductive layer 15 are connected to each other and the terminals (30A, 30A) of the semiconductor element 30 and the third conductive layer 15 are connected to each other; and, due to the via conductors (16D) of the third insulating resin layer 16, the third conductive layer 15 and the fourth conductive layer 17 are connected to each other.

A solder resist layer 25 is laminated on the outermost fourth conductive layer 17 of the build-up layer 24. Multiple pad holes are formed in the solder resist layer 25. Portions of the fourth conductive layer 17 that are respectively exposed from the pad holes become pads 26. A metal film 27 including a nickel layer, a palladium layer and a gold layer is formed on each of the pads 26.

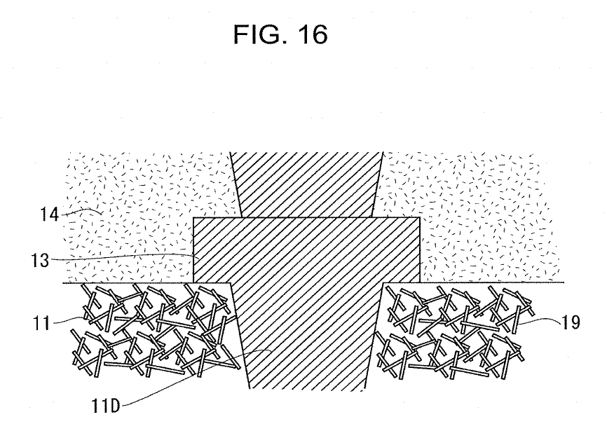

The insulating resin layers (11, 14, 16) are all each formed from a resin sheet of a B-stage (for example, a prepreg, an insulating film for a build-up substrate, and the like). Here, in the wiring substrate 10 of the present embodiment, among the multiple insulating resin layers (11, 14, 16), the first insulating resin layer 11 contains a fibrous or cloth-like reinforcing material 19 such as a glass cloth (see FIG. 16), whereas the second and third insulating resin layers (14, 16) do not contain a fibrous or cloth-like reinforcing material. Hereinafter, the fibrous or cloth-like reinforcing material is simply referred to as a “reinforcing material.” Further, the first insulating resin layer 11 has a thickness larger than each of thicknesses of the second and third insulating resin layers (14, 16).

Further, among the via conductors (14D) of the second insulating resin layer 14, the via conductors (14D) (corresponding to “third vias” according to an embodiment of the present invention) that connect between the second conductive layer 13 and the third conductive layer 15 each have a top diameter substantially the same as that of each of the via conductors (11D) (corresponding to “second vias” according to an embodiment of the present invention) of the first insulating resin layer 11, whereas, among the via conductors (14D) of the second insulating resin layer 14, the via conductors (14D) (corresponding to “first vias” according to an embodiment of the present invention) that connect between the terminals (30A, 30A) of the semiconductor element 30 and the third conductive layer 15 each have a top diameter smaller than that of each of the via conductors (11D) of the first insulating resin layer 11. Along with that the second insulating resin layer 14 is thinner than the first insulating resin layer 11, the via conductors (14D) that connect between the second conductive layer 13 and the third conductive layer 15 are shorter than the via conductors (11D) of the first insulating resin layer 11 and each have a larger bottom diameter.

Next, a method for manufacturing the wiring substrate 10 of the present embodiment is described.

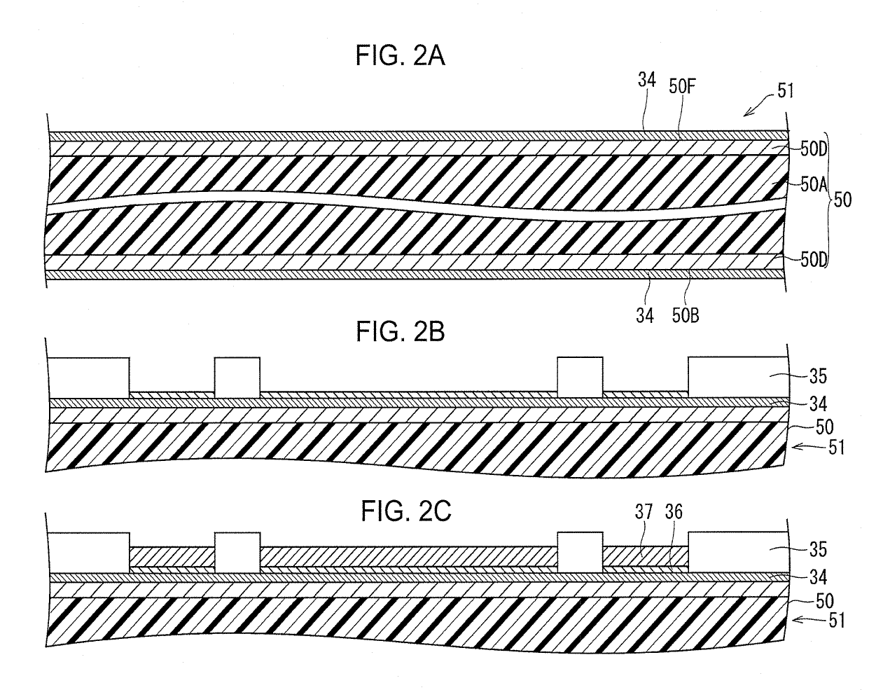

(1) As illustrated in FIG. 2A, a support member 51 is prepared in which copper carriers (34, 34) (corresponding to “metal films” provided in a “support member” according to an embodiment of the present invention) are respectively laminated on an F surface (50F), which is a front side surface of a support substrate 50, and a B surface (50B), which is a back side surface of the support substrate 50. The support substrate 50 is formed by laminating a copper foil (50B) on both front side and back side surfaces of a resin layer (50A). The copper foil (50B) of the support substrate 50 and the carrier 34 are bonded to each other at their peripheral portions.

Since the same processing is performed on the carrier 34 on the F surface (50F) side of the support substrate 50 and on the carrier 34 on the B surface (50B) side of the support substrate 50, hereinafter, processing performed on the carrier 34 on the F surface (50F) side is described as an example.

(2) As illustrated in FIG. 2B, a plating resist 35 of a predetermined pattern is formed on the carrier 34 of the support member 51.

(3) As illustrated in FIG. 2C, a Ni electrolytic plating treatment is performed and a Ni plating layer 36 is formed on a portion of the carrier 34 exposed from the plating resist 35. Further, a Cu electrolytic plating treatment is performed and a copper plating layer 37 is formed on the Ni plating layer 36.

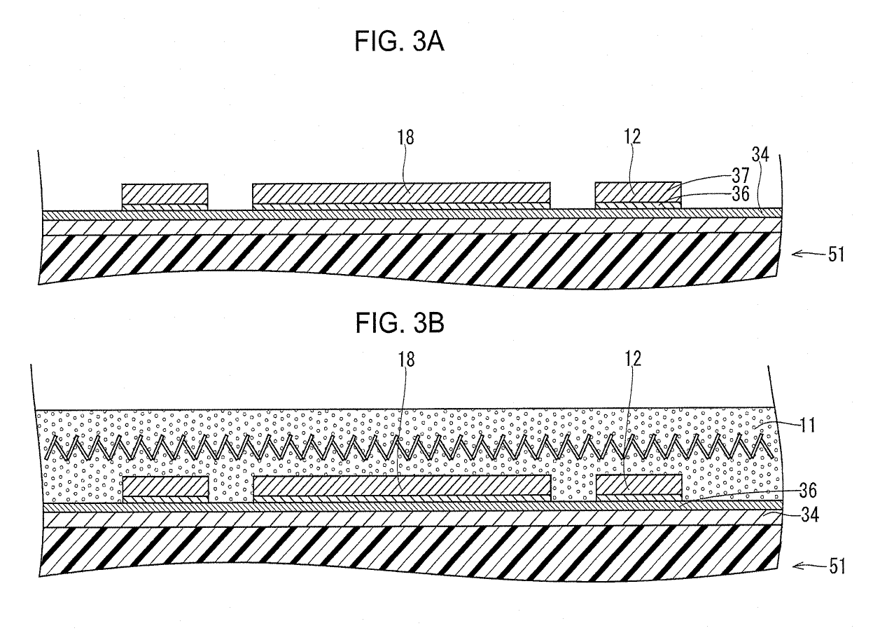

(4) The plating resist 35 is peeled off. As illustrated in FIG. 3A, the first conductive layer 12 including the conductive paths and the plane portion 18 is formed by the remaining copper plating layer 37.

(5) As illustrated in FIG. 3B, as the first insulating resin layer 11, a resin sheet containing the reinforcing material 19 (see FIG. 16) is laminated on the first conductive layer 12 and is hot pressed.

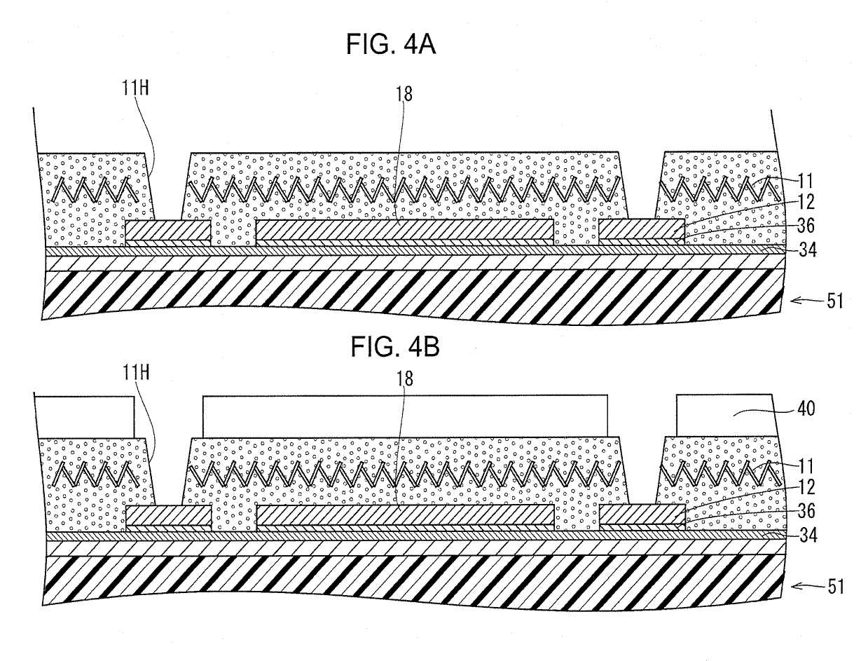

(6) As illustrated in FIG. 4A, CO₂ laser is irradiated to the first insulating resin layer 11, and the via holes (11H) are formed. The via holes (11H) are formed on the conductive paths of the first conductive layer 12.

(7) An electroless plating treatment is performed. An electroless plating film (not illustrated in the drawings) is formed on the first insulating resin layer 11 and in the via holes (11H).

(8) As illustrated in FIG. 4B, a plating resist 40 of a predetermined pattern is formed on the electroless plating film.

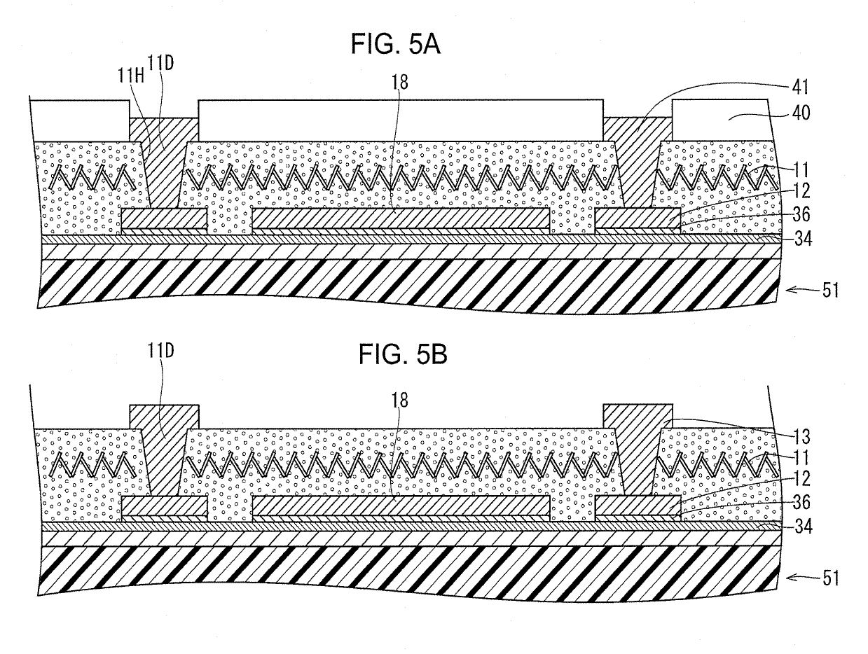

(9) An electrolytic plating treatment is performed. As illustrated in FIG. 5A, the via holes (11H) are filled with plating and the via conductors (11D) are formed. Further, an electrolytic plating film 41 is formed on a portion of the electroless plating film (not illustrated in the drawings) on the first insulating resin layer 11, the portion being exposed from the plating resist 40.

(10) The plating resist 40 is removed, and the electroless plating film (not illustrated in the drawings) under the plating resist 40 is removed. As illustrated in FIG. 5B, the second conductive layer 13 is formed on the first insulating resin layer 11 by the remaining electrolytic plating film 41 and electroless plating film. Then, the first conductive layer 12 and the second conductive layer 13 are connected to each other by the via conductors (11D).

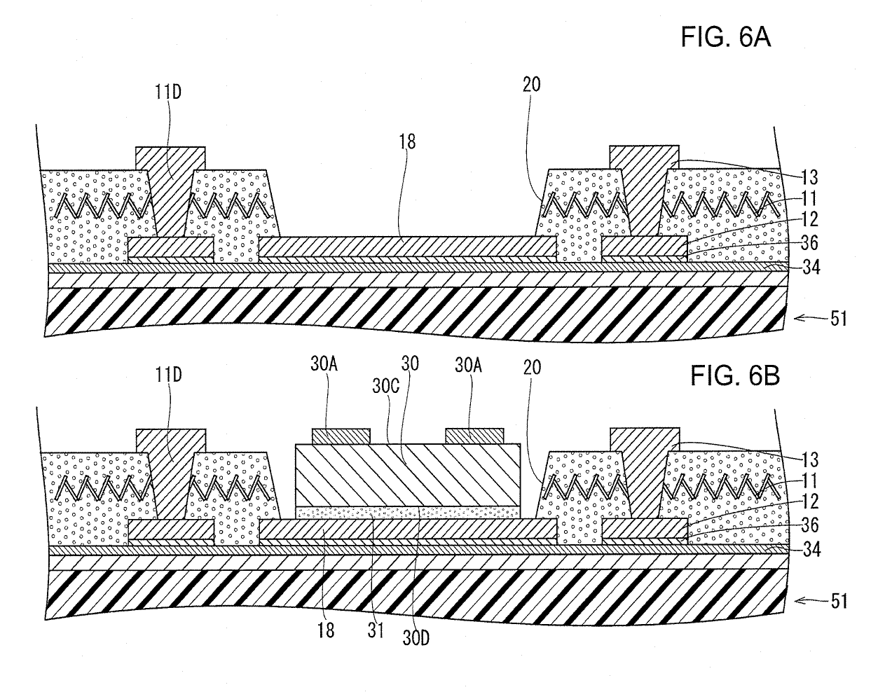

(11) As illustrated in FIG. 6A, the cavity 20 is formed on the plane portion 18 of the first insulating resin layer 11 using CO₂ laser.

(12) As illustrated in FIG. 6B, the adhesive 31 is injected into the cavity 20. Thereafter, the semiconductor element 30 is accommodated in the cavity 20 by a mounter (not illustrated in the drawings). In this case, the semiconductor element 30 is positioned such that the terminals (30A, 30A) face upward.

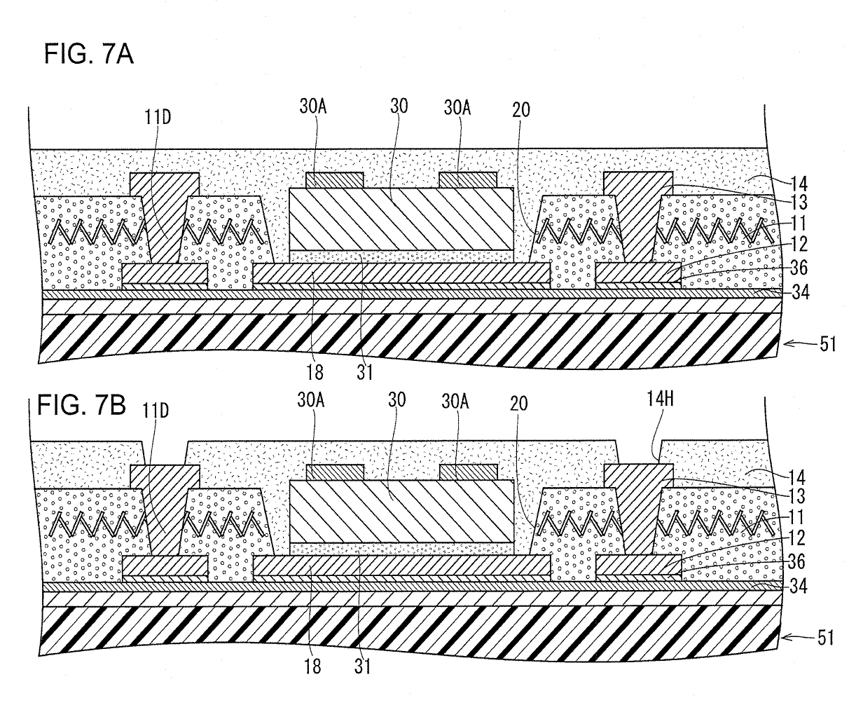

(13) As illustrated in FIG. 7A, as the second insulating resin layer 14, a resin sheet without a reinforcing material is laminated on the first insulating resin layer 11 from above the second conductive layer 13, and is hot pressed. In this case, the resin sheet is filled in between portions of the second conductive layer 13, and a thermosetting resin exuded from the resin sheet is filled in a gap between the inner surface of the cavity 20 and the semiconductor element 30.

(14) As illustrated in FIG. 7B, CO₂ laser is irradiated to the second conductive layer 13 of the second insulating resin layer 14, and the multiple via holes (14H) are formed.

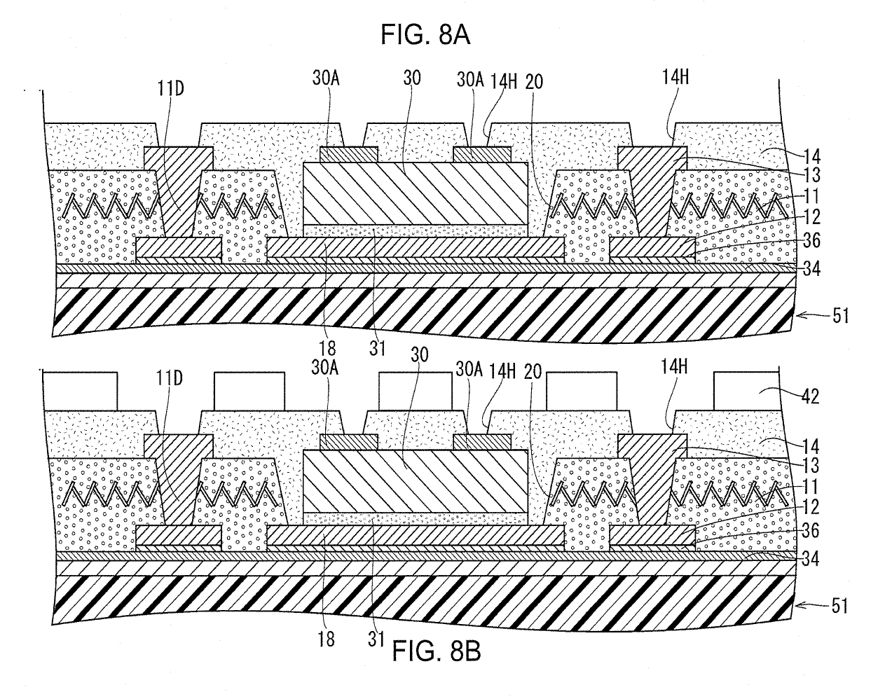

(15) As illustrated in FIG. 8A, UV laser is irradiated to the terminals (30A) of the semiconductor element 30 in the second insulating resin layer 14, and the via holes (14H) are formed each having a smaller diameter than that of each of the via holes (14H) on the second conductive layer 13.

(16) An electroless plating treatment is performed. An electroless plating film (not illustrated in the drawings) is formed on the second insulating resin layer 14 and in the via holes (14H).

(17) As illustrated in FIG. 8B, a plating resist 42 of a predetermined pattern is formed on the electroless plating film on the second insulating resin layer 14.

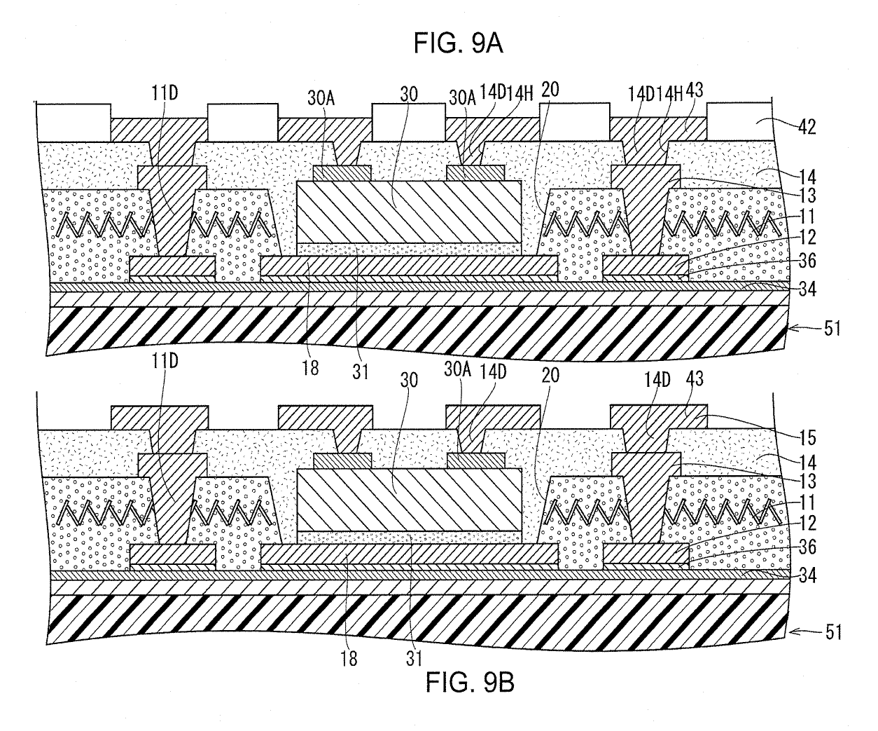

(18) An electrolytic plating treatment is performed. As illustrated in FIG. 9A, the via holes (14H) are filled with plating and the via conductors (14D) are formed. Further, an electrolytic plating film 43 is formed on a portion of the electroless plating film (not illustrated in the drawings) on the second insulating resin layer 14, the portion being exposed from the plating resist 42.

(19) The plating resist 42 is removed, and the electroless plating film (not illustrated in the drawings) under the plating resist 42 is removed. As illustrated in FIG. 9B, the third conductive layer 15 is formed on the second insulating resin layer 14 by the remaining electrolytic plating film 43 and electroless plating film. Then, a state is achieved in which a portion of the third conductive layer 15 and the second conductive layer 13 are connected to each other by the via conductors (14D), and the other portion of the third conductive layer 15 and the semiconductor element 30 are connected to each other by the via conductors (14D).

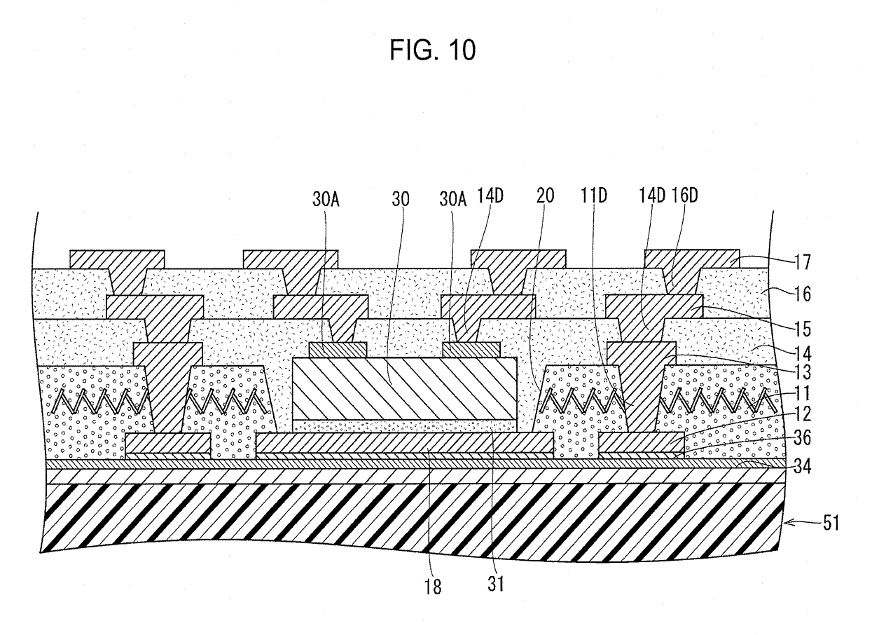

(20) By the processes as the above described (13)-(19), as illustrated in FIG. 10, the third insulating resin layer 16 and the fourth conductive layer 17 are formed on the third conductive layer 15, and a state is achieved in which the fourth conductive layer 17 and the third conductive layer 15 are connected to each other by the via conductors (16D).

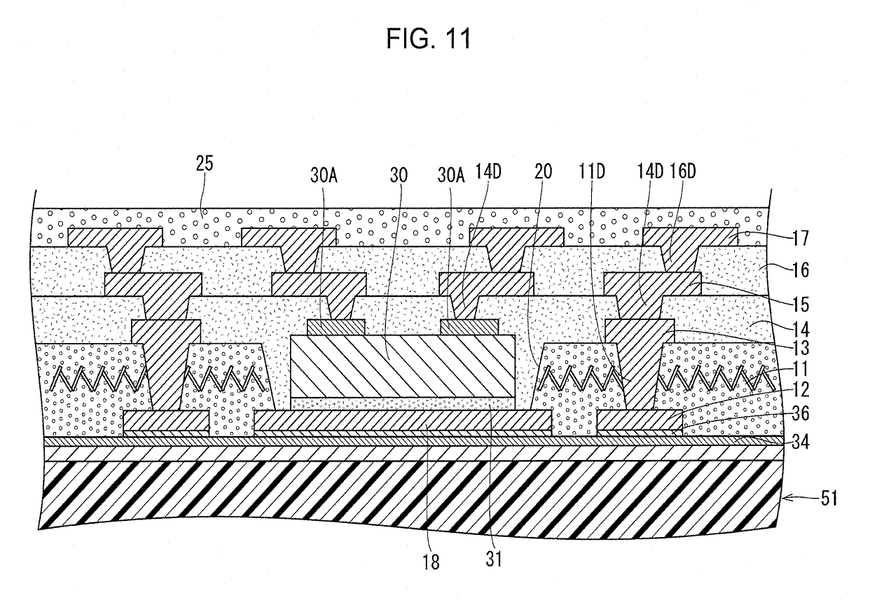

(21) As illustrated in FIG. 11, the solder resist layer 25 is laminated on the fourth conductive layer 17.

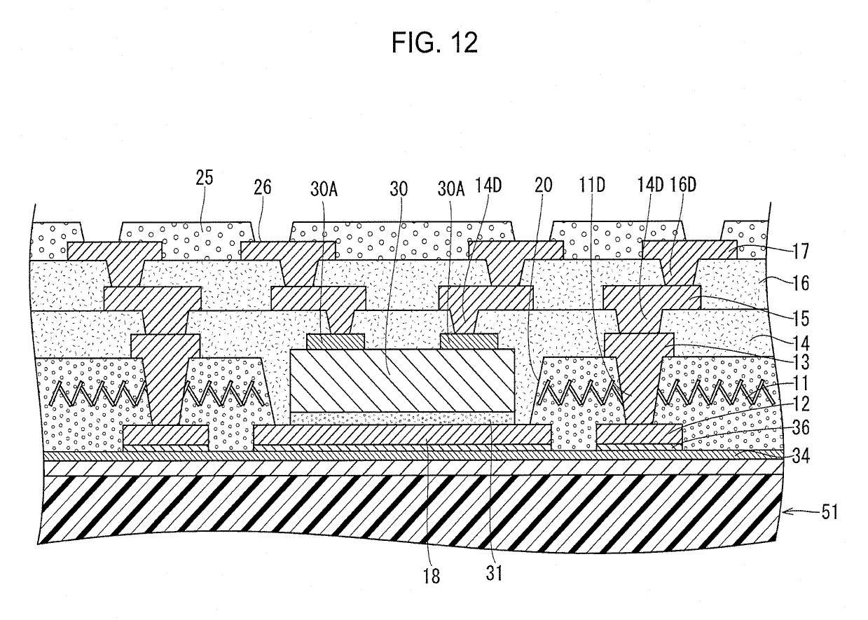

(22) As illustrated in FIG. 12, tapered pad holes are formed at predetermined places in the solder resist layer 25, and portions of the fourth conductive layer 17 exposed from the pad holes become the pads 26.

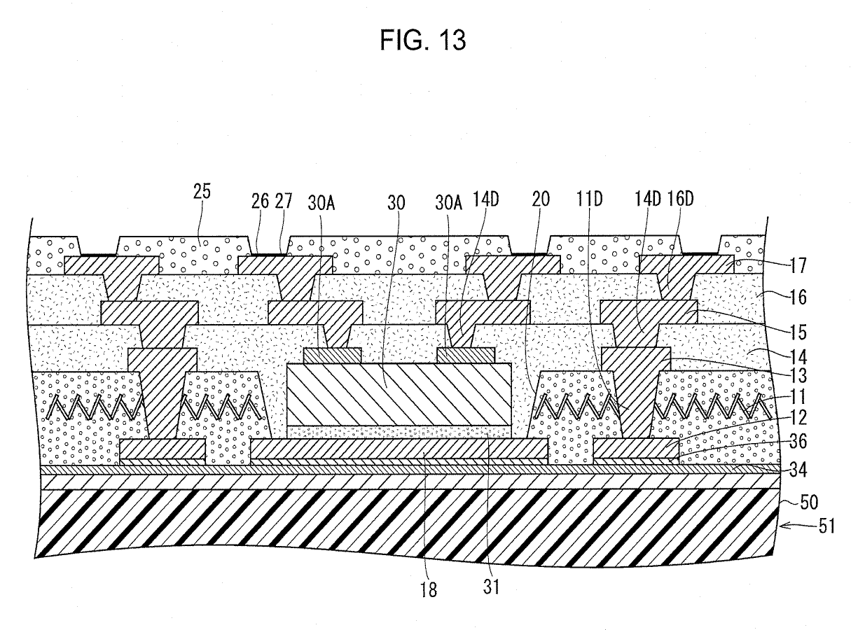

(23) On each of the pads 26, a nickel layer, a palladium layer and a gold layer are laminated in this order and a metal film 27 illustrated in FIG. 13 is formed. Instead of the metal film 27, it is also possible to perform a surface treatment using OSP (preflux).

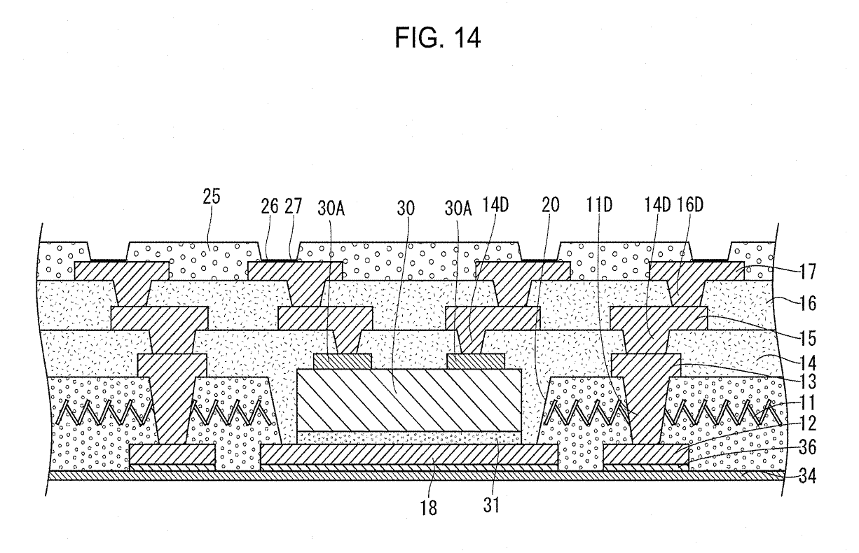

(24) As illustrated in FIG. 14, the resulting substrate is peeled off from the support substrate 50.

(25) The carrier 34 and the Ni plating layer 36 are respectively removed by etching. As a result, the wiring substrate 10 illustrated in FIG. 1 is completed.

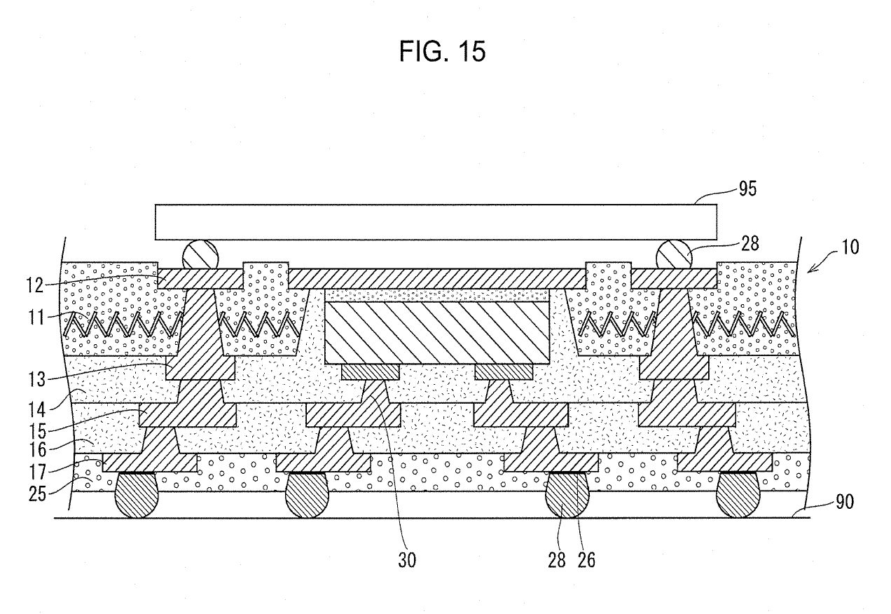

The description about the structure and the manufacturing method of the wiring substrate 10 of the present embodiment is as given above. Next, an example of use and an operation effect of the wiring substrate 10 are described. For example, as illustrated in FIG. 15, the wiring substrate 10 of the present embodiment is used by connecting the fourth conductive layer 17 side to a motherboard 90 and mounting an electronic component 95 such as a CPU to the first conductive layer 12 side. Specifically, solder bumps 28 are formed on the pads 26. In a state in which the solder bumps 28 face the motherboard 90, the wiring substrate 10 is place on the motherboard 90. Further, solder bumps 28 are also formed on lower surfaces of some of the conductive paths of the first conductive layer 12, and the electronic component 95 is mounted on the solder bumps 28.

However, in the wiring substrate 10 of the present embodiment, the multiple insulating resin layers (11, 14, 16) include one insulating layer (the first insulating resin layer 11) that is formed by a resin sheet containing a reinforcing material 19. Therefore, as compared to a case where all insulating resin layers are each formed by a resin sheet that does not contain a reinforcing material 19, strength can be improved.

Here, it is also conceivable to allow all insulating resin layers to be each formed from a resin sheet containing a reinforcing material 19. However, in a resin sheet containing a reinforcing material 19, it is difficult to reduce a diameter of a via conductor as compared to a resin sheet without a reinforcing material 19, and thus it is likely to be difficult to form a dense (fine) wiring pattern. Along with this, when all the insulating resin layers are each formed from a resin sheet containing a reinforcing material 19, a problem can occur that the thickness of the wiring substrate is increased.

In contrast, in the wiring substrate 10 of the present embodiment, among the multiple insulating resin layers (11, 14, 16), only the first insulating resin layer 11 contains the reinforcing material 19. Therefore, the strength can be improved, and an increase in diameter of the via conductors and a decrease in density of the wiring pattern can be minimized. As a result, the top diameter of each of the via conductors (14D) that connect between the semiconductor element 30 and the third conductive layer 15 can be made smaller than the top diameter of each of the via conductors (11D) of the first insulating resin layer 11. Further, an increase in total thickness of the wiring substrate 10 can also be prevented.

In addition, the first insulating resin layer 11 that accommodates the semiconductor element 30 is selected as the insulating resin layer containing the reinforcing material 19. Therefore, strength of a surrounding portion of the semiconductor element 30 can be improved and occurrence of a failure in the semiconductor element 30 can be prevented. Further, the insulating resin layer accommodating the semiconductor element 30 is likely to be thicker than other insulating resin layers. Therefore, by allowing the relatively thick insulating resin layer to contain the reinforcing material 19, improvement in strength can be further achieved.

Further, in the wiring substrate 10 of the present embodiment, the first conductive layer 12 is embedded in the first insulating resin layer 11. Therefore, as compared to a case where the first conductive layer 12 is formed on the secondary surface (11B) of the first insulating resin layer 11, the total thickness of the wiring substrate 10 can be reduced. Further, the lower surface of the first conductive layer 12 is positioned on an inner side of the secondary surface (11B) of the first insulating resin layer 11. Therefore, unnecessary contact between the first conductive layer 12 and the electronic component 95 can be suppressed.

### Second Embodiment

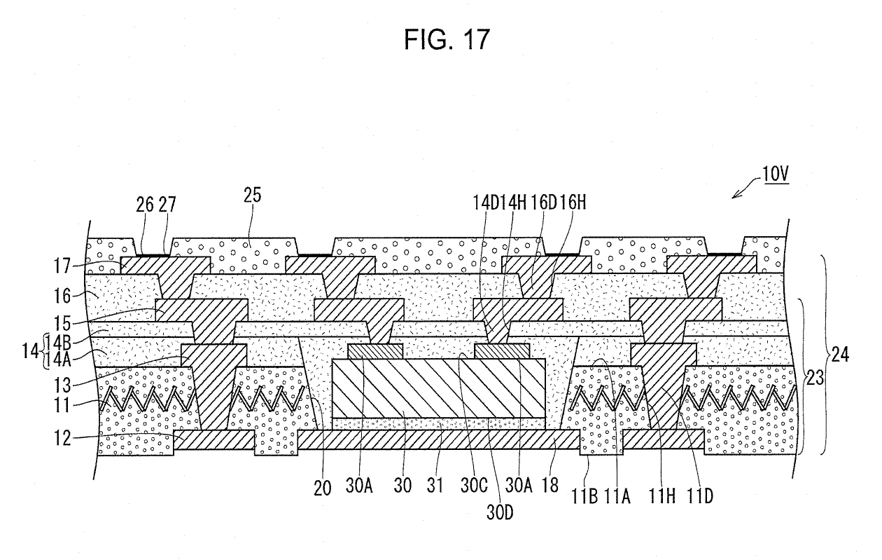

A wiring substrate (10V) of a second embodiment is different from the above wiring substrate 10 of the first embodiment in that the second insulating resin layer 14 has a two-layer structure. Specifically, as illustrated in FIG. 17, the second insulating resin layer 14 includes a first layer (14A) and a second layer (14B). The first layer (14A) is formed on the first insulating resin layer 11 side and covers the second conductive layer 13, and there is no conductive layer formed on an upper surface of the first layer (14A). The second layer (14B) is formed between the first layer (14A) and the third insulating resin layer 16, and the third conductive layer 15 is formed on an upper surface of the second layer (14B).

The cavity 20 of the present embodiment penetrates both the first insulating resin layer 11 and the first layer (14A) of the second insulating resin layer 14, and the second layer (14B) of the second insulating resin layer 14 enters the cavity 20 and covers the semiconductor element 30. In the present embodiment, of the cavity 20, a portion formed in the first insulating resin layer 11 corresponds to an “accommodating part” according to an embodiment of the present invention, and a portion formed in the second layer (14B) of the second insulating resin layer 14 corresponds to a “through hole” according to an embodiment of the present invention.

In the following, with respect to a method for manufacturing the wiring substrate (10V) of the present embodiment, a difference from the above first embodiment is mainly described.

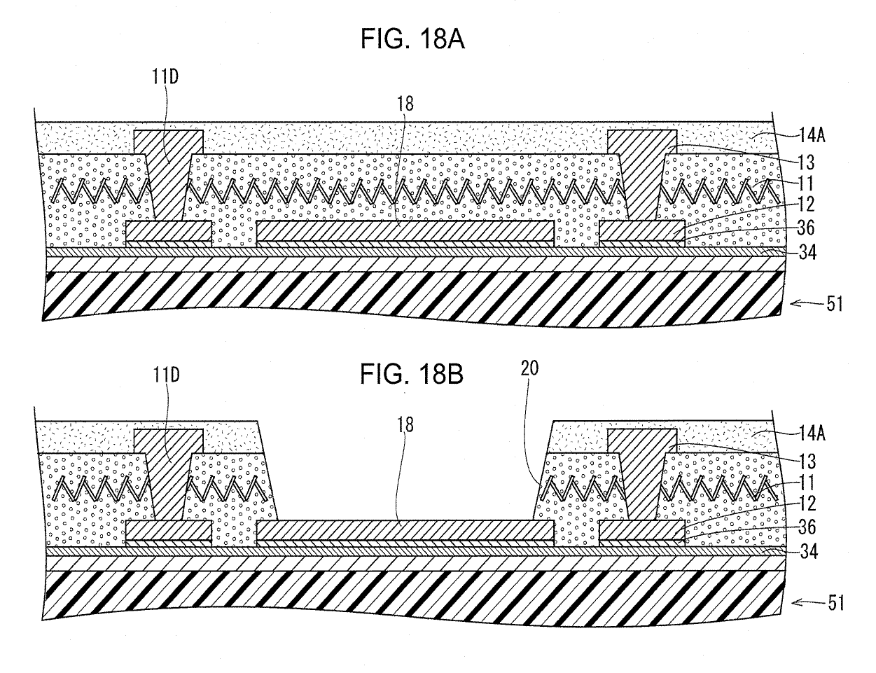

(1) Following the process (10) of the manufacturing method of the first embodiment, as illustrated in FIG. 18A, as the first layer (14A) of the second insulating resin layer 14, a resin sheet without a reinforcing material is laminated on the first insulating resin layer 11 from above the second conductive layer 13, and is hot pressed. In this case, spaces between portions of the second conductive layer 13 are filled with the resin sheet.

(2) As illustrated in FIG. 18B, the cavity 20 is formed on the plane portion 18 of the first insulating resin layer 11 and the first layer (14A) using CO₂ laser.

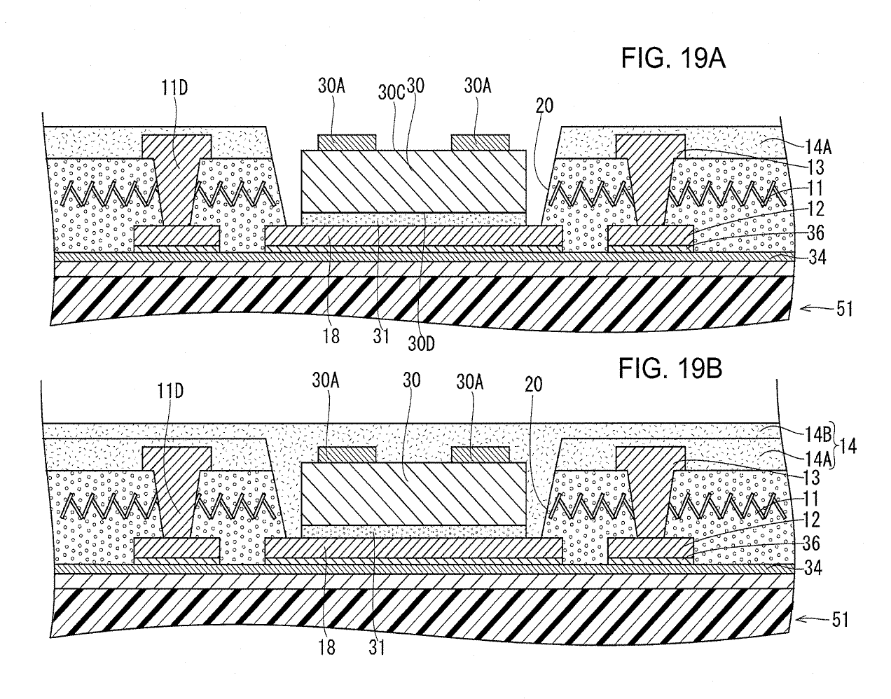

(3) As illustrated in FIG. 19A, the adhesive 31 is injected into the cavity 20. Thereafter, the semiconductor element 30 is accommodated in the cavity 20 by a mounter (not illustrated in the drawings). In this case, the semiconductor element 30 is positioned such that the terminals (30A, 30A) face upward.

(4) As illustrated in FIG. 19B, as the second layer (14B) of the second insulating resin layer 14, a resin sheet without a reinforcing material is laminated on the first layer (14A), and is hot pressed. In this case, a thermosetting resin exuded from the resin sheet is filled in a gap between an inner surface of the cavity 20 and the semiconductor element 30, and covers the semiconductor element 30.

(5) Processes same as the processes (14)-(25) of the manufacturing method of the first embodiment are performed. As a result, the wiring substrate (10V) of the present embodiment illustrated in FIG. 17 is completed.

According to the present embodiment, the second conductive layer 13 is covered by the first layer (14A) before the formation of the cavity 20. Therefore, for example, after the formation of the cavity 20, when resin residues on the plane portion 18 are removed, that a part of the second conductive layer 13 is erroneously removed can be prevented.

### Other Embodiments

The present invention is not limited to the above-described embodiments. For example, embodiments described below are also included in the technical scope of the present invention. Further, in addition to the embodiments described below, the present invention can also be embodied in various modified forms within the scope without departing from the spirit of the present invention.

In the above embodiments, one semiconductor element 30 is accommodated in one cavity 20. However, it is also possible that multiple semiconductor elements 30 are accommodated in one cavity 20.

In the above embodiments, the first insulating resin layer 11 is thicker than the second and third insulating resin layers (14, 16). However, it is also possible that the second and third insulating resin layers (14, 16) are thick, or the two have the same thickness.

In the above embodiments, the top diameter of each of the via conductors (14D) that connect between the second conductive layer 13 and the third conductive layer 15 is substantially the same as the top diameter of each of the via conductors (11D) of the first insulating resin layer 11. However, it is also possible that the top diameter of each of the via conductors (14D) that connect between the second conductive layer 13 and the third conductive layer 15 is smaller than the top diameter of each of the via conductors (11D) of the first insulating resin layer 11.

In the above embodiments, the wiring substrate is used by connecting the fourth conductive layer 17 side to the motherboard 90 and mounting the electronic component 95 such as a CPU on the first conductive layer 12 side. However, it is also possible that the positions of the motherboard 90 and the electronic component 95 are reversed.

In the above embodiments, the copper plating layer 37 that becomes the first conductive layer 12 is formed after the Ni plating layer 36 is formed on the carrier 34. However, it is also possible that the copper plating layer 37 that becomes the first conductive layer 12 is directly formed.

In the above embodiments, three insulating resin layers are provided. However, it is also possible that two insulating resin layers are provided, or four or more insulating resin layers are provided.

In the above embodiments, a conductive layer is not formed on the first layer of the second insulating resin layer 14. However, it is also possible that a conductive layer is formed on the first layer.

In the above embodiments, the first conductive layer 12 is embedded in the first insulating resin layer 11. However, it is also possible that the first conductive layer 12 is laminated on the first insulating resin layer 11.

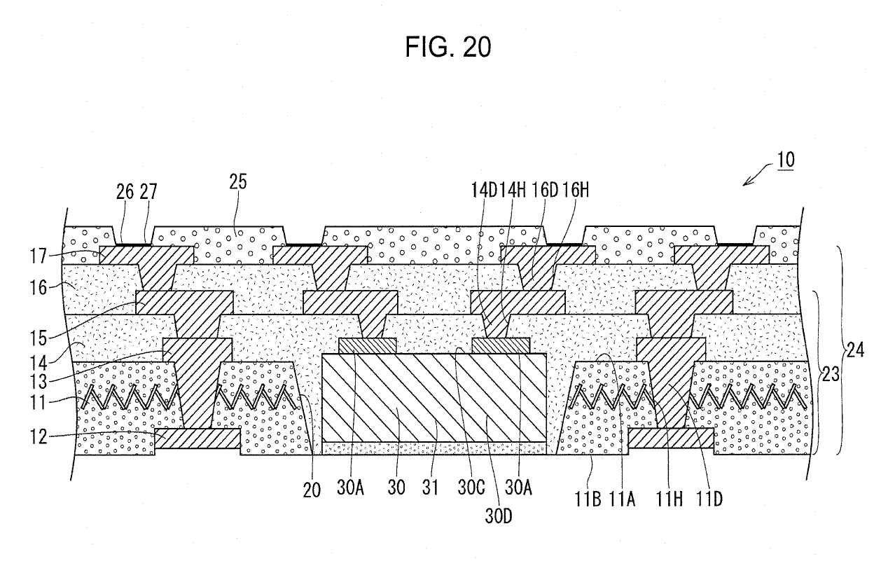

In the above embodiments, the plane portion 18 to which the semiconductor element 30 is provided in the first conductive layer 12. However, as illustrated in FIG. 20, it is also possible that the plane portion 18 is not provided and the adhesive 31 under the semiconductor element 30 is exposed.

In the above embodiments, only the first insulating resin layer 11 is an insulating resin layer that is formed from a resin sheet containing a reinforcing material 19. However, it is also possible that the third insulating resin layer 16 is also formed from a resin sheet containing a reinforcing material 19.

In the above embodiments, the “fibrous or cloth-like reinforcing material” is a glass cloth. However, the present invention is not limited to this. It is also possible that the “fibrous or cloth-like reinforcing material” is a carbon fiber, a glass non-woven fabric, an aramid cloth, an aramid non-woven fabric, or the like, or a combination of these.

A wiring substrate according to an embodiment of the present invention is formed by laminating multiple conductive layers and multiple insulating layers, the conductive layers each including a conductive path and being insulated from each other by the insulating layer. The wiring substrate includes: a first insulating layer that is formed at one end in a lamination direction among the multiple insulating layers, and contains a fibrous or cloth-like reinforcing material; an accommodating part that penetrates the first insulating layer; a semiconductor element that is accommodated in the accommodating part; a first conductive layer that is formed on a secondary surface side of the first insulating layer, the secondary surface being a surface of the first insulating layer on the one end side in the lamination direction; a second conductive layer that is formed on a primary surface side of the first insulating layer, the primary surface being a surface on an opposite side of the one end in the lamination direction; and a second insulating layer that is laminated on the first insulating layer and covers the second conductive layer and the semiconductor element, and is filled in a gap between an inner surface of the accommodating part and the semiconductor element, and does not contain a fibrous or cloth-like reinforcing material.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a plurality of insulating layers including a first insulating layer such that the first insulating layer is positioned at one end of the plurality of insulating layers in a lamination direction and has an accommodating portion penetrating through the first insulating layer;
a plurality of conductive layers laminated on the insulating layers and including a first conductive layer formed on one end side of the first insulating layer in the lamination direction and a second conductive layer formed on an opposite side of the first insulating layer with respect to the one end side in the lamination direction; and
a semiconductor element accommodated in the accommodating portion of the first insulating layer,
wherein the plurality of insulating layers includes the first insulating layer comprising a reinforcing material and a second insulating layer laminated on the first insulating layer such that the second insulating layer is covering the second conductive layer and the semiconductor element and filling a gap formed between the first insulating layer and the semiconductor element in the accommodating portion and does not contain a reinforcing material.

2. A wiring substrate according to claim 1, wherein the plurality of conductive layers is formed such that the first conductive layer is embedded in the first insulating layer and has an exposed surface on the one end side of the first insulating layer.

3. A wiring substrate according to claim 2, wherein the first conductive layer is embedded in the first insulating layer such that the exposed surface of the first conductive layer is recessed inward with respect to a surface of the first insulating layer on the one end side of the first insulating layer.

4. A wiring substrate according to claim 1, wherein the semiconductor element has a non-active surface on the one end side of the first insulating layer and an active surface on the opposite side of the first insulating layer with respect to the one end side in the lamination direction such that the active surface has a terminal structure and the non-active surface has no terminal structure, and the first conductive layer has a plane portion partially exposed in the accommodating portion of the first insulating layer and bonded to the non-active surface of the semiconductor element in the accommodating portion of the first insulating layer.

5. A wiring substrate according to claim 1, wherein the second insulating layer comprises a first layer and a second layer formed such that the first layer is covering the second conductive layer on the first insulating layer and that the second layer is formed on the first layer.

6. A wiring substrate according to claim 1, wherein the first insulating layer is formed such that the reinforcing material comprises at least one of a glass cloth, a carbon fiber, a glass non-woven fabric, an aramid cloth and an aramid non-woven fabric.

7. A wiring substrate according to claim 1, wherein the plurality of insulating layers is formed such that the insulating layers do not contain a reinforcing material other than the first insulating layer.

8. A wiring substrate according to claim 1, wherein the plurality of insulating layers includes a third insulating layer formed on the second insulating layer such that the third insulating layer does not contain a reinforcing material, and the plurality of conductive layers includes a third conductive layer formed on the second insulating layer and a fourth conductive layer formed on the third insulating layer such that the fourth conductive layer comprises a plurality of pads.

9. A wiring substrate according to claim 1, further comprising:
a plurality of via conductors formed in the plurality of insulating layers,
wherein the plurality of conductive layers includes a third conductive layer formed on the second insulating layer, and the plurality of via conductors includes a first via conductor and a second via conductor such that the first via conductor is connecting the first conductive layer and the second conductive layer through the first insulating layer and that the second via conductor is connecting the semiconductor element and the third conductive layer through the second insulating layer and has a via diameter which is smaller than a via diameter of the first via conductor.

10. A wiring substrate according to claim 9, wherein the plurality of via conductors includes a third via conductor formed such that the third via conductor is connecting the second conductive layer and the third conductive layer through the second insulating layer and has a via diameter which is substantially equal to the via diameter of the second via conductor:

11. A wiring substrate according to claim 2, wherein the semiconductor element has a non-active surface on the one end side of the first insulating layer and an active surface on the opposite side of the first insulating layer with respect to the one end side in the lamination direction such that the active surface has a terminal structure and the non-active surface has no terminal structure, and the first conductive layer has a plane portion partially exposed in the accommodating portion of the first insulating layer and bonded to the non-active surface of the semiconductor element in the accommodating portion of the first insulating layer.

12. A wiring substrate according to claim 2, wherein the second insulating layer comprises a first layer and a second layer formed such that the first layer is covering the second conductive layer on the first insulating layer and that the second layer is formed on the first layer.

13. A method for manufacturing a wiring substrate, comprising:
forming, on a support member, a plurality of insulating layers including a first insulating layer such that the first insulating layer is positioned at one end of the plurality of insulating layers in a lamination direction and has an accommodating portion penetrating through the first insulating layer, and a plurality of conductive layers laminated on the insulating layers and including a first conductive layer formed on one end side of the first insulating layer in the lamination direction and a second conductive layer formed on an opposite side of the first insulating layer with respect to the one end side in the lamination direction; and
removing the support member from the insulation and conductive layers,
wherein the forming of the insulation and conductive layers comprises forming the first conductive layer on the support member, forming the first insulating layer on the support member such that the first insulating layer covers the first conductive layer on the support member, forming the accommodating portion in the first insulating layer such that the accommodating portion penetrates through the first insulating layer, accommodating a semiconductor element in the accommodating portion of the first insulating layer such that the semiconductor element is positioned in the accommodating portion of the first insulating layer, forming the second conductive layer on the first insulating layer such that the second conductive layer is formed on the opposite side of the first insulating layer with respect to the first conductive layer, and forming the second insulating layer on the first insulating layer such that the second insulating layer covers the second conductive layer and the semiconductor element, fills a gap formed between the first insulating layer and the semiconductor element in the accommodating portion and does not contain a reinforcing material, the removing of the support member comprises removing the support member from the first insulating layer such that the semiconductor element is accommodated in the accommodating portion of the first insulating layer before the support member is removed from the first insulating layer, and the plurality of insulating layers includes the first insulating layer comprising a reinforcing material.

14. A method for manufacturing a wiring substrate according to claim 13, wherein the forming of the first insulating layer on the support member comprises covering the first conductive layer on the support member such that the first conductive layer on the support member is embedded in the first insulating layer.

15. A method for manufacturing a wiring substrate according to claim 13, wherein the support member has a metal film, and the removing of the support member from the first insulating layer comprises removing the support member from the first insulating layer such that the metal film is removed from the support member and that the metal film is etched from the first insulating layer.

16. A method for manufacturing a wiring substrate according to claim 15, wherein the support member has a second metal film formed on the metal film such that the second metal film comprises a metal material different from the metal film and the first conductive layer and is formed on part of the metal film on which the first conductive layer is to be formed, and the removing of the support member from the first insulating layer comprises removing the support member from the first insulating layer such that the second metal film is etched from the first conductive layer after the metal film is etched from the first insulating layer.

17. A method for manufacturing a wiring substrate according to claim 15, wherein the semiconductor element has a non-active surface on the one end side of the first insulating layer and an active surface on the opposite side of the first insulating layer with respect to the one end side in the lamination direction such that the active surface has a terminal structure and the non-active surface has no terminal structure, the forming of the accommodating portion comprises forming a plane portion of the first conductive layer such that the plane portion is partially exposed in the accommodating portion of the first insulating layer, and the accommodating of the semiconductor element in the accommodating portion of the first insulating layer comprises bonding the non-active surface of the semiconductor element to the plane portion of the first conductive layer partially exposed in the accommodating portion of the first insulating layer.

18. A method for manufacturing a wiring substrate according to claim 13, wherein the forming of the second insulating layer comprises forming a first layer of the second insulating layer on the first insulating layer such that the first layer of the second insulating layer covers the second conductive layer, the forming of the accommodating portion in the first insulating layer comprises forming the accommodating portion such that a penetrating hole penetrating through the first layer of the second insulating layer is formed and that the accommodating portion is formed to penetrate through the first insulating layer from the penetrating hole, and the forming of the second insulating layer comprises forming a second layer of the second insulating layer on the first layer of the second insulating layer and the semiconductor element such that the second layer of the second insulating layer covers the semiconductor element and fills the gap formed between the first insulating layer and the semiconductor element in the accommodating portion.

19. A method for manufacturing a wiring substrate according to claim 13, wherein the first insulating layer is formed such that the reinforcing material comprises at least one of a glass cloth, a carbon fiber, a glass non-woven fabric, an aramid cloth and an aramid non-woven fabric.

20. A method for manufacturing a wiring substrate according to claim 13, wherein the plurality of insulating layers is formed such that the insulating layers do not contain a reinforcing material other than the first insulating layer.
